(19) United States
(12) Patent Application Publication
(10) Pub. No.: US 2011/0084778 A1
(43) Pub. Date: Apr. 14, 2011

(54) ELECTRICAL CIRCUIT SIGNAL CONNECTION SYSTEM

(76) Inventors: Patrick Zabinski, Stewartville, MN (US); Chad Smutzer, Rochester, MN (US)

(21) Appl. No.: 12/578,383

(22) Filed: Oct. 13, 2009

(51) Int. Cl. H03H 7/38; H01P 1/00

(52) U.S. Cl. 333/33; 333/24 R

(57) ABSTRACT

A termination block for connecting a first signal device and a second signal device. The termination block includes a housing, first and second connectors, and an electrical circuit having passive elements that connect the first and second connectors and provide impedance matching.

### CROSS-REFERENCE TO RELATED APPLICATIONS

This application claims priority to U.S. patent application Ser. No. 12/185,636, filed Aug. 4, 2008, which claims priority to U.S. patent application Ser. No. 11/327,908, filed Jan. 9, 2006, and issued as U.S. Pat. No. 7,408,425 on Aug. 5, 2008, which claims priority to U.S. Provisional Patent Application Ser. No. 60/644,351, filed on Jan. 14, 2005, all entitled “DIFFERENTIAL SIGNAL TERMINATION BLOCK,” the disclosures of which are hereby incorporated by reference.

### BACKGROUND

As the demand for higher performance electronics continues to push data rates beyond 1 GHz, there is a growing trend to use differential signal protocols in electronics. Yet, there is a lack of appropriate test equipment being developed to properly characterize such signals.

Specifically, the majority of developing differential signal protocols are developed around the concept of considering only the differential portion of the signal and suppressing and ignoring the common-mode portion of the signal. By doing so, shifts in common-mode voltage, balanced impedance discontinuities in interconnect, and noise from outside sources can often be of little consequence to the serial link performance. Accordingly, many transmission line drivers and receivers provide good differential impedance match between the true and complement signal while the common-mode impedance match is often quite poor.

In contrast, the vast majority of available test equipment is designed with coaxial connections that are inherently best suited for single-ended signal protocols. Through the use of two such coaxial connectors, the equipment can provide or capture differential signals by considering only the difference between these two connection points through internal circuitry. With the use of single-ended connectors, the test equipment typically terminates the connections with 50 Ohm resistors to ground. Looking at the difference in potential between the true and complement ports, a 100 Ohm series resistance can be measured and is sometimes adequate termination for the incoming differential signal.

The disparity between the terminations and impedance matching approaches used in the differential signal protocols and the test equipment with single-ended test equipment can sometimes cause problems. For example, Low Voltage Differential Signaling (LVDS) drivers assume a far-end termination of 100 Ohms between the true and complement differential signals with high impedance to ground potential. When such a driver is connected to typical test equipment with a 50 Ohm single-ended resistance to ground, the driver output signal swing is degraded, the common-mode voltage is reduced, and the signal shape is distorted. Similarly, when a function generator or similar test equipment expecting a 50 Ohm termination to ground drives a LVDS receiver having a 100 Ohm termination between its differential inputs, the signals are distorted in shape, level, and swing.

### SUMMARY

In accordance with one aspect, a termination block is provided for coupling a first signal device to a second signal device. The termination block is comprised of a housing that supports a first and second set of connectors and an electrical circuit comprised of passive circuit elements that connect the first set of connectors to the second set. The electrical circuit can provide impedance matching between a first signal device and a second signal device. The signal devices may be a differential signal device or a single-ended signal device.

In accordance with another aspect, the electrical circuit provides a balanced load for a differential signal device and a matched impedance on a single-ended signal device. In one embodiment, the termination block includes electrically and geometrically symmetrical phase-matched connectors and passive elements in the true and complement signal paths to maintain a high signal quality.

### BRIEF DESCRIPTION OF THE DRAWINGS

FIG. 1 is a top view with part cut away of a first preferred embodiment of a termination block constructed in accordance with the present invention;

FIG. 2 is a side view of the termination block in FIG. 1;

FIG. 3 is a front view of the termination block of FIG. 1;

FIG. 4 is a partial view in cross-section taken along the plane 4-4 indicated in FIG. 1;

FIGS. 5 and 6 are circuit diagrams of two preferred sets of passive electrical components used in the termination block of FIG. 1;

FIG. 7 is a partial top view with part cut away of an alternative embodiment of a termination block constructed in accordance with the present invention;

FIGS. 8 and 9 are circuit diagrams of two preferred sets of passive electrical components used in the termination block of FIG. 7;

FIG. 10 is a circuit diagram of a preferred set of passive electrical components used in the termination block of FIG. 1;

FIG. 11 is a schematic depiction of a circuit for sampling a differential signal without changing the termination scheme or interfering with the signal;

FIG. 12 is a schematic depiction of a circuit providing an inductively-coupled biasing port;

FIG. 13 depicts a bidirectional circuit for improving impedance matching in accordance with the present invention;

FIG. 14 depicts a unidirectional circuit for improving impedance matching in accordance with the present invention;

FIG. 15 depicts another unidirectional circuit for improving impedance matching in accordance with the present invention;

FIG. 16 depicts a single-ended version of the circuit of FIG. 5;

FIG. 17 depicts a single-ended version of the circuit of FIG. 6;

FIG. 18 depicts a single-ended version of the circuit of FIG. 8;

FIG. 19 depicts a single-ended version of the circuit of FIG. 10;

FIG. 20 depicts a single-ended version of the circuit of FIG. 11;

FIG. 21 depicts a single-ended version of the circuit of FIG. 12;

FIG. 22 depicts a single-ended version of the circuit of FIG. 13;

FIG. 23 depicts a single-ended version of the circuit of FIG. 14;

FIG. 24 depicts a single-ended version of the circuit of FIG. 15;

FIG. 25 depicts a circuit that removes the DC portion of a signal to reduce common-mode noise and common-mode offset issues in accordance with the present invention;

FIG. 26 depicts a circuit that provides a pair of inductively-coupled biasing ports to adjust the common-mode portion of a differential signal in accordance with the present invention;

FIGS. 27A and 27B respectively provide a top and side view of a block housing in accordance with the present invention;

FIGS. 28A and 28B respectively provide a top and side view of another block housing in accordance with the present invention;

FIG. 29 depicts a differential pass-through device with sampling ports for 10 percent coupled signal in accordance with the present invention;

FIG. 30 depicts a single-ended version of the circuit of FIG. 29;

FIG. 31 depicts a differential, terminated device with sampling ports for 10 percent coupled signal in accordance with the present invention; and

FIG. 32 depicts a single-ended version of the circuit of FIG. 31.

### DETAILED DESCRIPTION

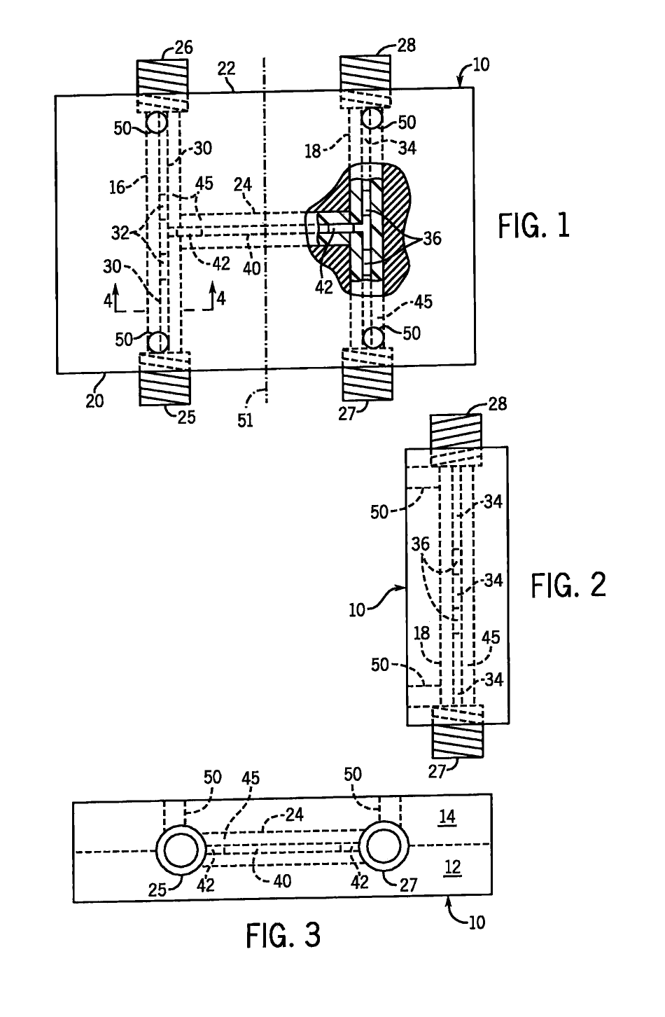

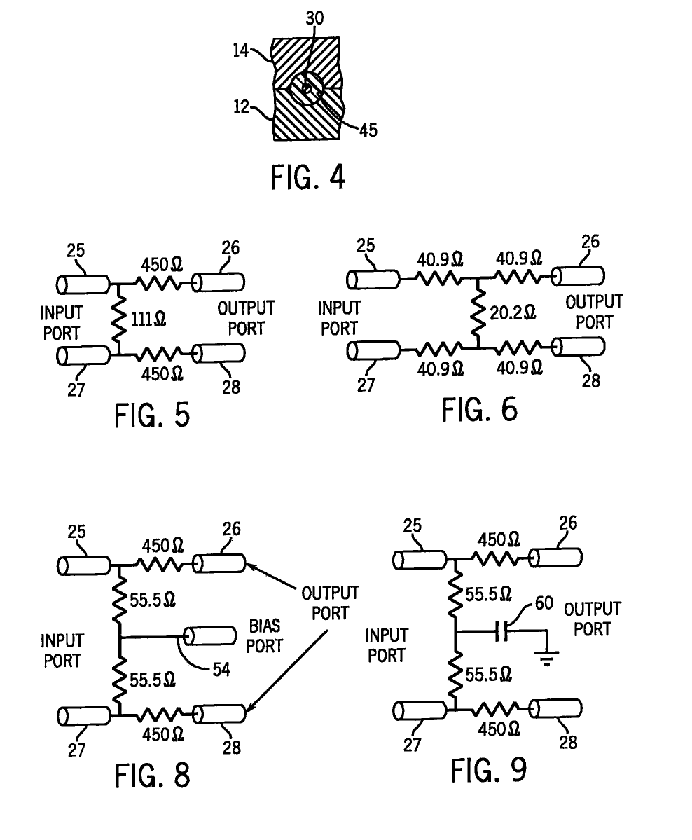

Referring particularly to FIGS. 1-4, a preferred embodiment of the invention is a termination block having a housing 10 formed by two substantially identical, rectangular components that form a lower base 12 and a top 14. The components 12 and 14 are formed from metal and act as a shield to the electronic components contained therein. At the juncture of the top 14 and base 12 three circular-shaped channels are formed to support the electronic components. More specifically, a pair of parallel channels 16 and 18 extend completely through the housing 10 from its input side 20 to its output side 22, and a cross-channel 24 connects the parallel channels 16 and 18 at their midpoints. The resulting “H” shaped channel within the housing 10 has two openings to the input side 20 of the housing 10 and two openings on its output side 22.

Coaxial connectors 25-28 are mounted in these four openings to make electrical connections between the electronic components within the housing 10 and external circuitry (not shown in the drawings). Any of a number of different types of high-speed connectors can be used depending on the particular application such as K connectors (Model K102F) commercially available from Anritsu Company which are rated from DC through 40 GHz.

The electronic components in the housing 10 are a set of resistor elements electrically connected by metallic rods. More specifically, a metallic rod 30 is mounted coaxially in the parallel channel 16 and extends between connectors 25 and 26. The rod 30 is interrupted by passive resistive elements 32 that are also coaxial with the channel 16 and soldered securely to segments of the rod. The number of resistors 32 and their values will depend on the particular circuit used as will be described in more detail below.

Similarly, a metal rod 34 is mounted coaxially in the channel 18 and extends between connectors 27 and 28. Passive resistor elements 36 are soldered to the metal rod 34 and interrupt the direct conductive path it forms between connectors 27 and 28. As with resistors 32, the number and values of resistors 36 will depend on the particular application of the termination block.

A connecting rod 40 and passive resistor elements 42 are mounted coaxially in the cross channel 24. The connecting rod 40 electrically connects between the conductive rods 30 and 34 at their midpoints and the resistor elements 42 are soldered to the connecting rod segments and interrupt the direct connection. The number of resistors 42 used and the values thereof will depend on the particular application as described below.

The rods 30, 34 and 40 as well as the resistors they support are disposed coaxially in the channels 16, 18 and 24 and interconnect the four connectors 25-28. These elements are surrounded by a dielectric insulating material 45 which fills the annular spaces around them. Four fill holes 50 are formed through the top 14 to enable the dielectric material to be injected in liquid form into the channels 16, 18 and 24 after the termination block is assembled. The fill holes 50 are located near each connector 25-28 so that when the dielectric material is injected through one of the fill holes 50, it flows through all the channels and pushes air out through the other three fill holes 50. A dielectric material such as RTP 100 polypropylene (PP) commercially available from the RTP Company of Winona, Minn. may be used and it hardens after injection into the channels 16, 18 and 24.

A very rigid and symmetrical structure is thus formed to insure precise phase matching for the differential signal across connectors 25 and 27. More specifically, the termination block is electrically symmetrical about a central plane indicated at 51 in FIG. 1. The central plane 51 passes through the housing 10 midway between the differential input connector 25 and 27 and midway between output connectors 26 and 28. The electrical symmetry is secured in the preferred embodiment by also laying out the components and supporting structures such that they are also physically symmetrical about the central plane 51.

A number of different circuit component configurations can be used in the termination block structure of FIG. 1. Referring particularly to FIG. 5, a first embodiment presents a matching differential impedance at the input across connectors 25 and 27 when the output connectors are terminated to a single-ended signal device. It includes three passive resistive elements having values of 450 Ohms, 111 Ohms and 450 Ohms. This embodiment presents a 100 Ohm differential input impedance to a differential signal device connected across the connectors 25 and 27 and a 50 Ohm single-ended output impedance to a single-ended signal device connected to connector 26 or 28. The common-mode impedance to ground across the differential input connectors 25 and 27 is 450+50=500 Ohms, which is significantly higher than the 50 Ohms seen with a direct connection to a single-ended signal device. This high input impedance avoids “pulling-down” differential signals and distorting them. The signal at output connectors 26 and 28 is one tenth the signal across input connectors 25 and 27. To maintain balanced impedance at the differential inputs, a 50 Ohm termination cap is fastened to the unused single-ended connector 26 or 28 when only one connector 26 or 28 is needed.

A variation of this circuit is shown in FIG. 6. Here the circuit is symmetric and the input across connectors 25 and 27 and the output at connectors 26 and 28 are treated the same. This embodiment includes five passive resistive elements having values of 40.9 Ohms, 40.9 Ohms, 20.2 Ohms, 40.9 Ohms and 40.9 Ohms. This circuit enables bidirectional connection between driving and driven circuitry. With the smaller series resistor values, the common-mode impedance to ground is 40.9+40.9+50=131.8 Ohms. The differential signal at connectors 26 and 28 is one tenth the differential signal applied across connectors 25 and 27, and when driven in the other direction, the differential signal across connectors 25 and 27 is one-tenth the signal applied to either connector 26 or 28 when the output connectors are terminated to a single-ended signal device.

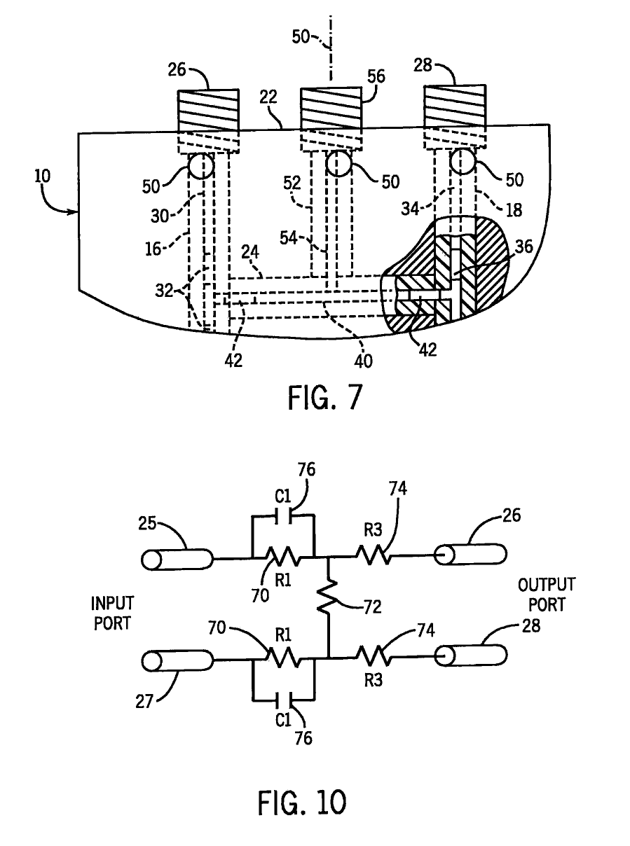

An alternative embodiment of the termination block is illustrated in FIG. 7 which enables a number of additional circuits to be used. In this alternative embodiment the structure is the same as that described above except that a third parallel channel 52 is formed in the housing 10 midway between the channels 16 and 18 on the output side of the housing 10. A metallic rod 54 extends along the centerline of the channel 52. The rod 54 connects the midpoint on the conductive rod 40 to a coaxial connector 56 mounted to the output side of the housing 10. As with the other parallel channels, a fill hole 50 is formed near the connector 56 to enable the annular space around the rod 54 to be filled with a dielectric insulating material. In addition, the coaxial connector 56 and the conductive rod 54 are disposed in the central plane 51 so as not to upset the symmetry thereabout.

The additional channel 52 and connector 56 enable common-mode signal control. Referring to the embodiment in FIG. 8 the conductive rod 54 enables the common-mode point to be set to a specific DC voltage. This is accomplished by connecting a DC bias source through a bias port 83 of the desired voltage level to the connector 56.

Yet another embodiment of the invention enables common-mode decoupling. Referring to FIG. 9, in some test environments high levels of common-mode noise are produced and the attached equipment is sensitive to common-mode noise. To alleviate some of these problems a capacitor 60 is connected between the common-mode point and circuit ground. This capacitor 60 can be an external component connected to the connector 56, or it can be inserted at a break in the conductive rod 54 and located inside the housing 10 as one of the passive electrical components.

Another embodiment of the invention provides not only balanced impedance matching, but also passive equalization to the differential signal across connectors 25 and 27. Referring to FIG. 10, resistors 70 connected to differential signal connectors 25 and 27 cooperate with parallel connected capacitors 76 to provide a high-pass transfer function that frequency compensates for the low-pass transfer function associated with lossy transmission lines that connect to the termination block. The values of resistors 70 and the remaining resistors 72 and 74 are selected to provide the desired impedance matching and the value of capacitors 76 is selected to provide the desired frequency compensation.

It should be apparent that many variations are possible without departing from the spirit of the invention. While the physical construction described above is preferred, other constructions are possible. For example, the conductive paths and passive electronic components can be formed as a circuit on an insulating substrate, and the substrate firmly mounted within the housing and electrically attached to the coaxial connectors. The layout of the circuit on the substrate should be such that the geometric and electrical symmetry is maintained about the central plane 51.

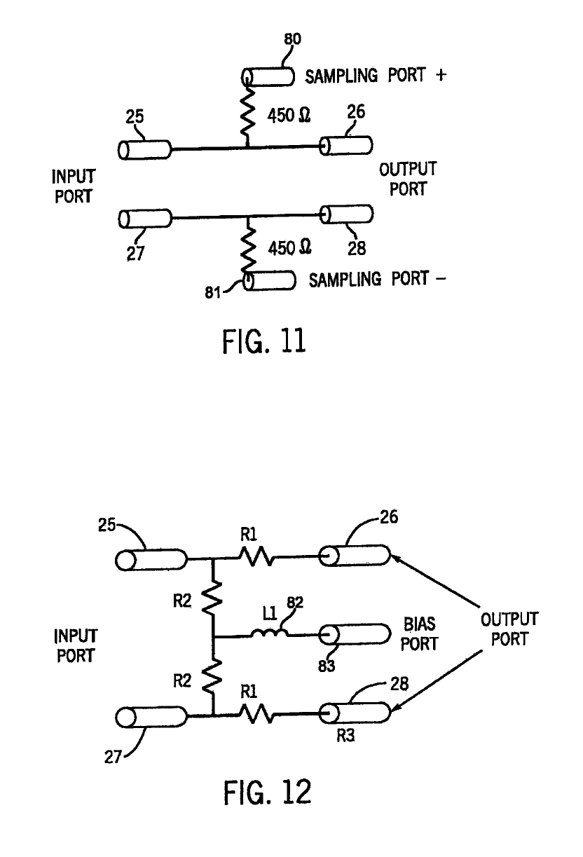

In many situations, it is useful to sample a differential signal without changing its termination scheme or interfering with the signal. The circuit of FIG. 11 provides such functionality by passing through the differential signal from the input ports 25 and 27 to the output ports 26, 28 while tapping off a small portion of the signal to the sampling ports 80, 81 at relatively high impedance. The signal portion and impedance can vary, though in the depicted case 10 percent of the signal is tapped off to the sampling port at an impedance of 500 Ohms and assuming the test equipment input is 50 Ohms to ground.

Referring to FIGS. 8 and 12, an application of the circuit of FIG. 8 is to enable a user to inject a DC bias voltage at the midpoint of the termination through the bias port 83. While the circuit works well under many conditions, in some cases there can be undesirable effects related to the bias port 83 when a DC voltage is injected. Most DC power supplies have some amount of AC noise, which can be referred to as “ripple.” Noise from a DC power supply is directly injected into the circuit, thus degrading the signal's integrity. To alleviate signal degradation, the circuit of FIG. 12 inserts an inductor 82 in series with the bias port 83 to attenuate AC noise on the injected voltage signal. As a result, the differential voltages at the input ports 25, 27 and output ports 26, 28 will not be degraded by the noise present at the bias port 83.

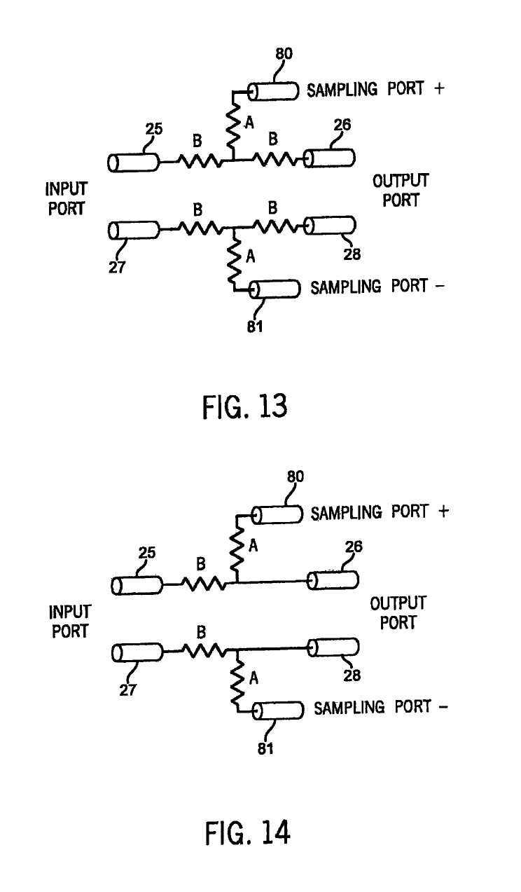

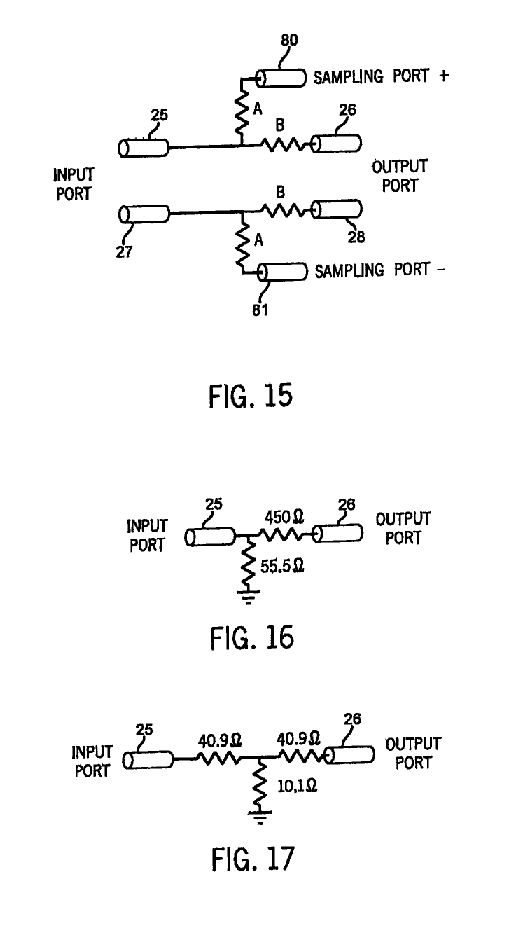

Referring now to FIGS. 13-15, in some cases there are undesirable effects when using the circuit of FIG. 11 in situations where its input or output impedances do not match the surrounding environment. In general, impedance mismatches can allow appreciable portions of injected signals to be reflected back through the circuit and be injected back into the source device. Using passive resistive components, the input or output impedance can be matched to the external environment to prevent the unwanted reflections and thus not interfere with the source device. In particular, the circuits of FIGS. 13-15, which include resistors having impedances A and B offer significantly improved performance by matching the input or output impedances to a surrounding environment, for example, a 50 Ohm impedance. The circuit of FIG. 13 offers bi-directional application to provide improved ease-of-use in a test environment. It is contemplated that the impedances A and B of FIG. 13 are 20650/59=442 Ohms and 50/59=0.847 Ohms, respectively. The circuits of FIGS. 14 and 15 are uni-directional, that is, the input impedance is matched to a selected impedance while the output impedance is not.

It is contemplated that the impedances A and B of FIG. 14 are 450 Ohms and 5 Ohms, respectively, while the respective impedances A and B of FIG. 15 are 450 Ohms and 50/9=5.56 Ohms. A difference between the circuits of FIGS. 14 and 15 is that the location matching resistors having an impedance B are placed differently with relation to the input and output ports 25, 27 and 26, 28. The matching resistors of FIG. 14 are located between the input ports 25, 27 and the signal taps to provide increased isolation between the inputs and sampling ports. The matching resistors of FIG. 15 are located between the signal taps and the output ports 26, 28 to provide increased isolation between the sampling and output ports. The subtle differences between the circuits of FIGS. 13-15 can have an appreciable influence on the accuracy of a resulting signal measurement and they can each be used in appropriate circumstances to provide improved performance over the circuit of FIG. 11.

Turning now to the circuits provided in FIGS. 16-24, the above-discussed circuits are most appropriately employed with differential signals. However, there is value and applicability in adapting these circuits for use in single-ended applications. While the following circuits are described with respect to input and output ports 25 and 26, this could readily be adapted to use input and output ports 27 and 28 instead.

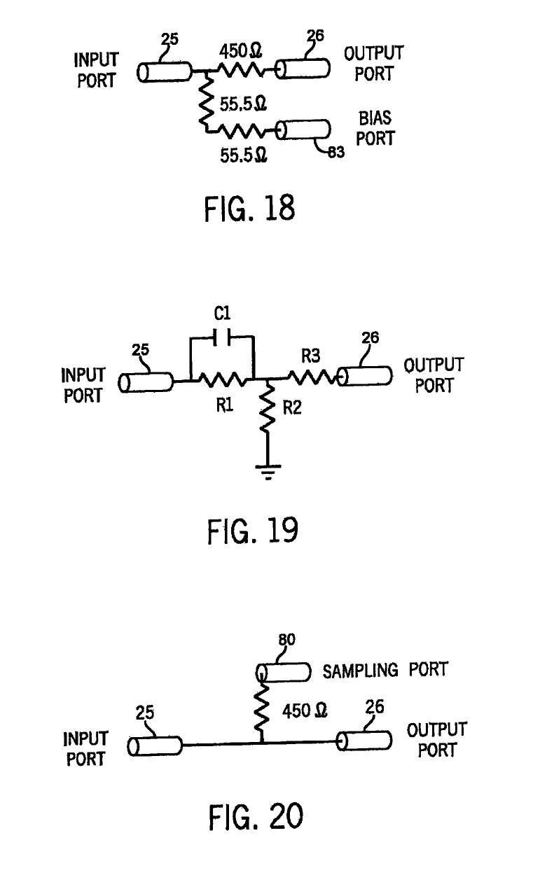

FIG. 16 shows the circuit of FIG. 5 adapted for use in single-ended applications. It includes a 55.5 Ohm passive resistive element to ground following the input port 25 and a 450 Ohm resistive element between the ground and the output port 26. FIG. 17 depicts the circuit of FIG. 6 adapted for use in single-ended applications. The circuit includes two 40.9 Ohm passive resistive elements spanning the input port 25 and output ports 26 and a 10.1 Ohm resistor to ground therebetween. The circuit of FIG. 18 is adapted from the circuit of FIG. 8 in order to accommodate single-ended applications and includes a 450 Ohm resistive element spanning the input port 25 and output port 26 and a 55.5 resistive element in series between the input port 25 and a bias port 83.

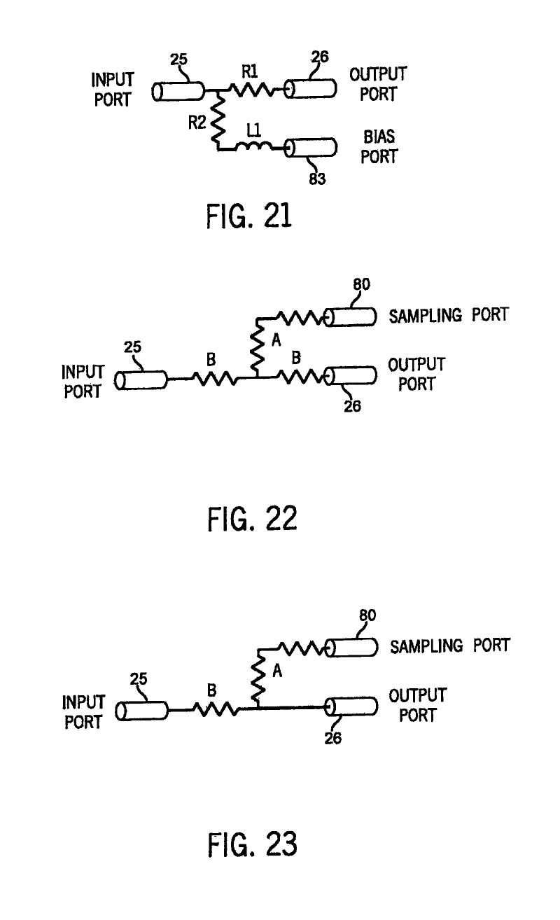

The circuit of FIG. 19 is adapted from that of FIG. 10 in order to accommodate single-ended applications. It includes a first resistive element having an impedance R1 in parallel with a capacitor having a capacitance C1 following the input port 25 running to a second resistive element having an impedance R3 preceding the output port 26. A resistive element with an impedance R2 to ground is included between the first and second resistive elements. FIG. 20 provides an adaptation of the circuit of FIG. 11 for single-ended applications. The circuit includes a 450 Ohm resistive element to a sampling port 80 between the input port 25 and output port 26. The circuit of FIG. 21 adapts that of FIG. 12 for single-ended applications and includes a first resistive element having an impedance R1 between the input and output ports 25 and 26. A second resistor having a resistance R2 in series with an inductor having an inductance L1 runs from the input port 25 to a bias port 83.

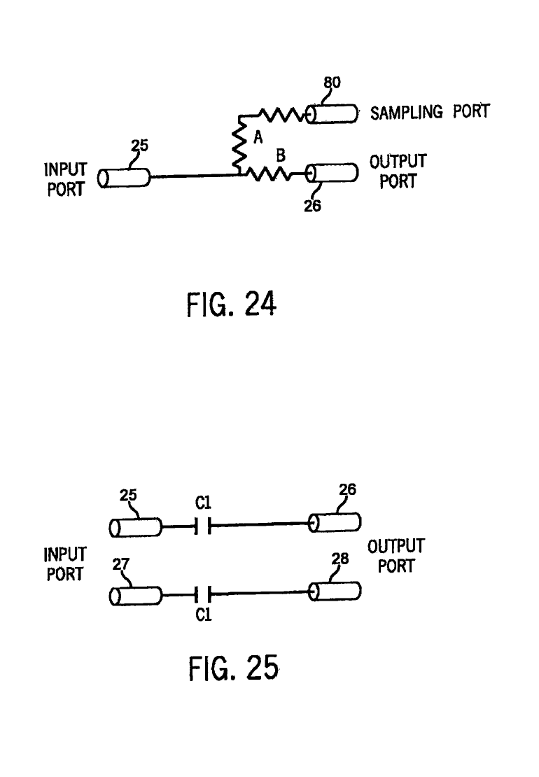

The circuit of FIG. 22 is an adaptation of that of FIG. 13 for single-ended applications and includes two resistive elements each having an impedance B between the input and output ports 25 and 26 and a connection to a sampling port having a resistors with an impedance A running therebetween. This arrangement offers bi-directional application by matching both input and output impedances to the surrounding environment. It is contemplated that the impedances A and B are 26050/59=442 Ohms and 50/59=0.847 Ohms, respectively. FIG. 23 provides a circuit adapted from that of FIG. 14 for single-ended applications in which the input impedance is matched to the surrounding environment, but the output impedance is not. The circuit includes a resistive element with an impedance B following the input port 25 and a connection to a sampling port including a resistive element with an impedance A preceding the output port. It is contemplated the impedances A and B are 450 Ohms and 5 Ohms, respectively. Likewise, FIG. 24 shows the circuit of FIG. 15 adapted for single-ended applications. It includes a connection to a sampling port having a resistive element with an impedance A in series and a resistive element with an impedance B preceding the output port. It is contemplated the impedances A and B are 450 Ohms and 50/9=5.56 Ohms, respectively.

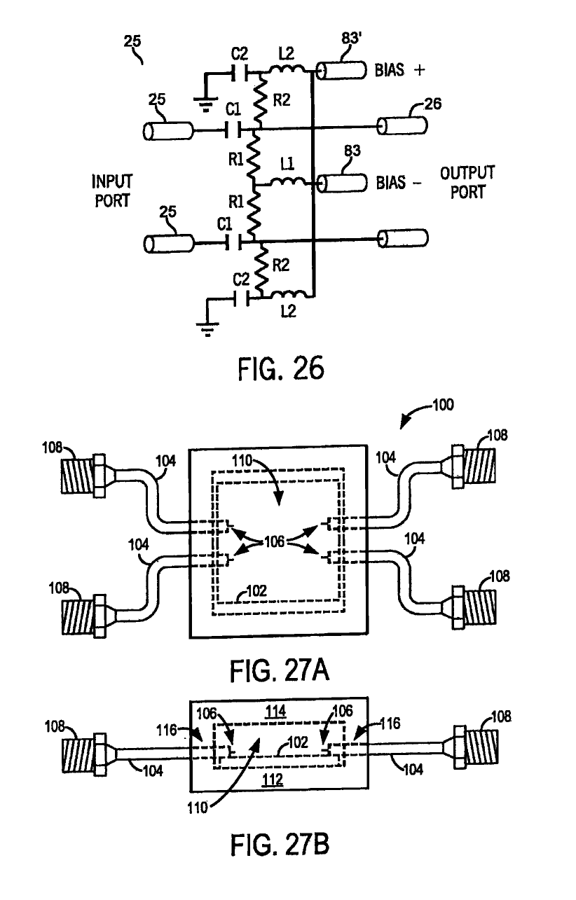

Referring now to FIGS. 25 and 26, it can be useful to remove the DC portion of a signal before the receiver to combat common-mode noise and offset issues. The circuit of FIG. 25 achieves this by blocking the DC signal with capacitors C1. Since the capacitors C1 pass through AC signals, the resulting waveform on the output ports 26, 28 will generally contain just the transient signal. Similarly, it is often useful to adjust the common-mode portion of a differential signal, particularly when transitioning from one signal protocol to another, for example, from Positive Emitter Coupled Logic (PECL) to Current Mode Logic (CML). The circuit of FIG. 26 performs this function using two steps. First, the common-mode portion of the input signal is stripped out using DC-blocking capacitors having a capacitance C1, thus leaving the AC signal with a common-mode voltage near zero. Second, a desired common-mode voltage is injected into the circuit using the resistors having impedances R1 and R2 with the two bias voltages BIAS+ and BIAS− via bias ports 83′, 83. To filter noise from the power supplies attached to the bias ports 83′, 83, inductors having an inductance L1 or L2 and capacitors having a capacitance C2 are optionally added. It should be noted that in cases where ground is used with one of the bias voltages, then the appropriate inductor and its associated bias port can be replaced with a direct connection to ground.

Referring now to FIGS. 27A and 27B, another termination block housing 100 is shown. The housing 100 includes a substrate 102 that can accommodate a circuit, such as the circuits depicted in FIGS. 5-6, 8-26, and 29-32. The circuit can be buried within the substrate 102 or assembled onto the substrate 102, for example, by soldering the circuit to the substrate's surface. The substrate 102 can, for example, be a printed circuit board or a thin- or thick-film ceramic. To provide access to the circuit, coaxial cables 104 are soldered or otherwise attached to the substrate's interconnect 106. The opposing end of the coaxial cables 104 include a coaxial connector 108 for easy connection to outside circuitry. To protect the circuitry, the substrate 102 is housed in a cavity 110 formed by a lower base 112, to which the substrate 102 may be adhered, and a top 114. The blocks are made of a material, such as plastic or metal, that provides physical protection to the substrate and cables. The base 112 and top 114 each include half-cylinder trenches 116 to accommodate and secure the coaxial cables 104. When the base 112 and the top 114 are joined together, opposing half-cylinders 116 align to form full-cylinder trenches that physically hold the coaxial cables 104 in place.

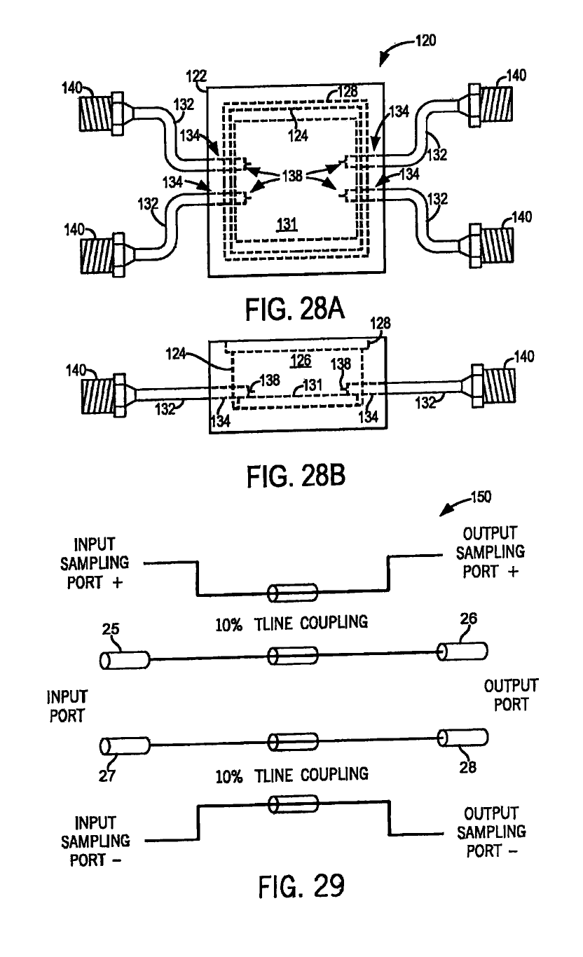

Referring to FIGS. 28A and 28B, a housing 120 similar to that of FIGS. 27A and 27B is provided. In place of two opposing blocks, that is, a base and top, single block 122 having a rectangular trench 124 form the cavity 126. The block 122 is partially open at one end formed by a second trench 128 configured to accommodate a lid 130. A substrate 131 configured to accommodate a circuit is mounted to an interior surface of the block 122 opposite the open end. Coaxial cables 132 are threaded through cylindrical holes 134 in the block 122 where they are attached to the substrates interconnect 138. On the opposing end of the coaxial cables 132 are coaxial connectors 140 to provide connectivity to outside circuitry. Again, the substrate 131 may be a printed circuit board or thin- or thick-film ceramic and the block 122 may be plastic, metal, or any other appropriate material that sufficiently protects the substrate and circuitry.

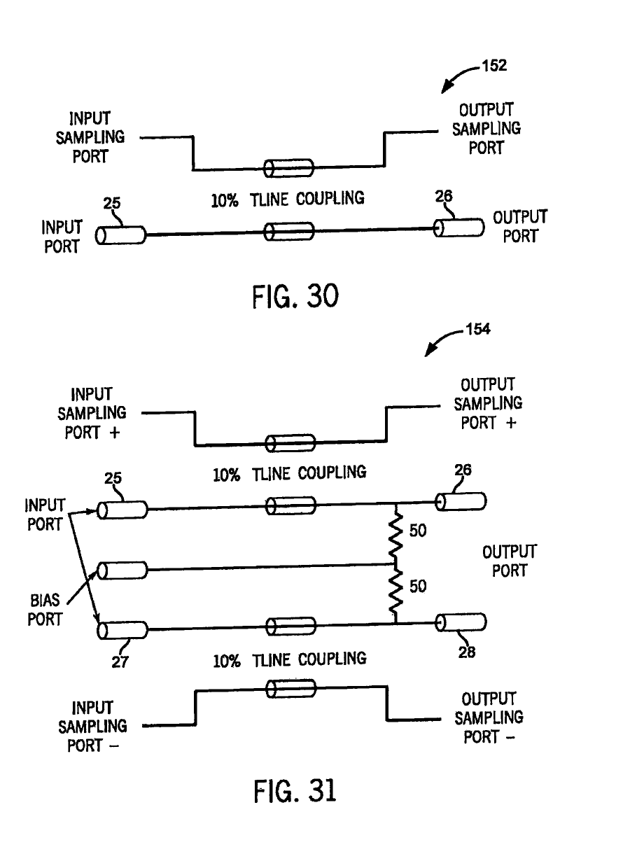

Referring to FIGS. 29-32, test and measurement equipment often has internal termination impedance. In many cases, this impedance is 50 Ohms to ground. While some high-speed protocols can tolerate or accommodate this termination, it can be advantageous to isolate the test equipment termination from the signal path. This can be accomplished using passive coupling. FIG. 29 shows a differential pass-through device 150 with sampling ports for 10 percent coupled signal. Both the pass through and the reflected signal sampling ports are shown. This device 150 can be inline with a full system link, allowing a downstream device to provide termination, thus reducing the impact of the measurement equipment on the primary signal. A similar, but single-ended pass through device 152 is shown in FIG. 30. It includes pass-through and reflected signal sampling ports for 10 percent coupled signal. This circuit can be placed in line with a full system link, allowing a downstream device to provide termination.

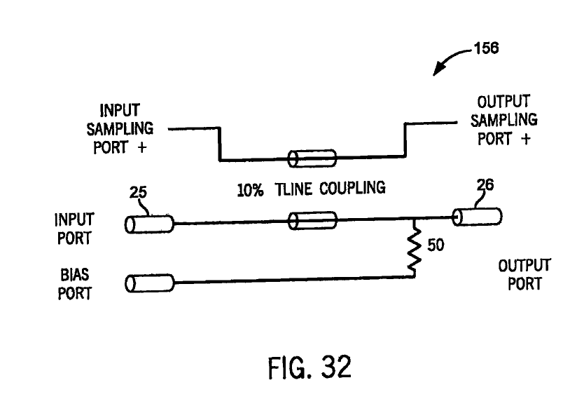

A differential, terminated device 154 with sampling ports for 10 percent coupled signal is shown in FIG. 31. A bias port is provided to allow flexible common-mode biasing of differential signals. The internal termination resistors provide appropriate high-speed termination while the test equipment loads and samples only the coupled portion of the signal. The input and output sampling ports can provide 10 percent of the signal to the test equipment. Similarly, a single-ended, terminated device 156 with sampling ports for 10 percent coupled signal is shown in FIG. 32. A bias port is provided to allow flexible input biasing of the signal. The internal termination resistor provides appropriate high-speed termination while the test equipment loads and samples only the coupled portion of the signal. Again, the input and output sampling ports can provide 10 percent of the signal to the test equipment.

The present invention has been described in terms of the various embodiments, and it should be appreciated that many equivalents, alternatives, variations, and modifications, aside from those expressly stated, are possible and within the scope of the invention. Therefore, the invention should not be limited to a particular described embodiment.

1. A circuit block for coupling signal devices for characterization of signals associated with the devices, the circuit block comprising:
a housing forming a cavity therein;
an input connector extending through the housing into the cavity and configured to be coupled to a first signal device;
an output connector extending through the housing into the cavity and configured to be coupled to a second signal device configured to characterize signals associated with the first signal device; and
an electrical circuit fixedly secured to the housing in the cavity and connected between the input connector and the output connector and configured to provide impedance matching between the first signal device and the second signal device, such that the second signal device can properly characterize signals associated with the first signal device.

2. The circuit block as recited in claim 1 wherein:
the input connector includes a first input connector and a second input connector, each extending through the housing into the cavity and configured to be coupled to the first signal device;
the output connector includes a first output connector and a second output connector, each extending through the housing into the cavity and configured to be coupled to the second signal device configured to characterize signals associated with the first signal device; and
the electrical circuit further includes a first electrical line linking the first input connector to the first output connector and a second electrical line linking the second input connector to the second output connector.

3. The circuit block as recited in claim 2 wherein the electrical circuit further includes a first sampling port connected to the first electrical line between the first input and output connectors via a first resistor and a second sampling port coupled to the second electrical line between the second input and output connectors via a second resistor, wherein the first and second sampling ports are configured to sample a differential signal between the first and second electrical lines substantially without changing a termination scheme of the differential signal.

4. The circuit as recited in claim 3 wherein the first and second resistors each have a resistance of 450 Ohms.

5. The circuit block as recited in claim 3 wherein the electrical circuit is configured to provide bidirectional current flow and the first electrical line includes a resistor between the first resistor and first input connector and a resistor between the first resistor and the first output connector and the second electrical line further includes a resistor between the second resistor and the second input connector and a resistor between the second resistor and the second output connector.

6. The circuit block as recited in claim 5 wherein the first and second resistors have a resistance of 442 Ohms and the other resistors have a resistance of 0.847 Ohms.

7. The circuit block as recited in claim 3 wherein the electrical circuit is configured to provide unidirectional current flow and the first electrical line includes a resistor between the first resistor and the first input connector and the second electrical line includes a resistor between the second resistor and the second input connector.

8. The circuit block as recited in claim 7 wherein the first and second resistors have a resistance of 450 Ohms and the other resistors have a resistance of 5 Ohms.

9. The circuit block as recited in claim 3 wherein the electrical circuit is configured to provide unidirectional current flow and the first electrical line includes a resistor between the first resistor and the first output connector and the second electrical line includes a resistor between the second resistor and the second output connector.

10. The circuit block as recited in claim 9 wherein the first and second resistors have a resistance of 450 Ohms and the other resistors have a resistance of 5.56 Ohms.

11. The circuit block as recited in claim 2 wherein the electrical circuit further includes a bias port configured to allow an injection of DC bias voltage into the electrical circuit.

12. The circuit block as recited in claim 11 wherein the bias port is coupled to the first electrical line via an inductor and a first resistor having a first resistance and coupled to the second electrical line via the inductor and a second resistor having the first resistance and wherein the first electrical line includes a resistor having a second resistance between the first resistor and the first output connector and the second electrical line includes a resistor having the second resistance between the second resistor and the second output connector.

13. The circuit block as recited in claim 2 wherein the first and second electrical lines each include a capacitor configured to reduce a common-mode component of a differential signal passing through the electrical circuit.

14. The circuit block as recited in claim 13 wherein the electrical circuit further includes a first and second bias port, each coupled to the first and second electrical lines between the capacitors and the first and second output connectors via an inductor and resistor, and configured to allow adjustment of the common-mode portion of the differential signal.

15. The circuit block as recited in claim 14 wherein the bias ports and resistors are configured to add a selected common-mode portion to the differential signal and the inductors and capacitors are configured to reduce noise associated with the bias ports.

16. The circuit block as recited in claim 2 wherein the electrical circuit further includes:
a third electrical line coupling the first input and output connectors to a first input sampling port and a first output sampling port; and
a fourth electrical line coupling the second input and output connectors to a second input sampling port and a second output sampling port

17. The circuit block as recited in claim 16 wherein the electrical circuit forms a differential pass-through circuit and the third and fourth electrical lines respectively provide a percentage coupling from the first and second electrical lines to the sampling ports

18. The circuit block as recited in claim 17 wherein the percentage coupling is approximately 10 percent.

19. The circuit block as recited in claim 16 wherein the electrical circuit further includes a bias port coupled to the first electrical line between the third electrical line and the first output connector via a first resistor and coupled to the second electrical line between the fourth electrical line and the second output port via a second resistor.

20. The circuit block as recited in claim 19 wherein the electrical circuit is a differential pass-through circuit, the transmission line coupling provides approximately 10 percent coupling between the electrical lines, the first and second resistors each have a resistance of 50 Ohms, and the bias port allows common-mode biasing of a differential signal between the first and second electrical lines.

21. The circuit block as recited in claim 1 wherein the electrical circuit includes a first electrical line coupling the input connector to the output connector.

22. The circuit block as recited in claim 21 wherein the electrical circuit further includes a ground line coupled to the first electrical line via a first resistor and the first electrical line includes a second resistor between the output connector and the first resistor.

23. The circuit block as recited in claim 22 wherein the first and second resistors have resistances of 55.5 Ohms and 450 Ohms, respectively.

24. The circuit block as recited in claim 22 wherein the first electrical line further includes third resistor between the first resistor and the input connector.

25. The circuit block as recited in claim 24 where the first resistor has a resistance of 10.1 Ohms and the second and third resistors each have a resistance of 40.9 Ohms.

26. The circuit block as recited in claim 21 wherein the electrical circuit further includes a bias port coupled to the first electrical line via a first resistor and the first electrical line includes a second resistor between the first resistor and the output connector.

27. The circuit block as recited in claim 26 wherein the first resistor has a resistance of 55.5 Ohms and the second resistor has a resistance of 450 Ohms.

28. The circuit block as recited in claim 21 wherein the electrical circuit further includes a bias port coupled to the first electrical line via an inductor and a first resistor in series and the first electrical line further includes a second resistor between the output port and the first resistor, wherein the bias port and first resistor are configured to inject a DC bias voltage into the electrical circuit and the inductor is configured to reduce noise associated with the bias port.

29. The circuit block as recited in claim 21 wherein the electrical circuit further includes a sampling port coupled to the first electrical line via a first resistor.

30. The circuit block as recited in claim 29 wherein the first resistor has a resistance of 450 Ohms.

31. The circuit block as recited in claim 29 wherein the first electrical line further includes a second resistor between the input connector and the first resistor and a third resistor between the output connector and the first resistor.

32. The circuit block as recited in claim 29 wherein the first resistor has a resistance of 442 Ohms and the second and third resistors each have a resistance of 0.847 Ohms.

33. The circuit block as recited in claim 29 wherein the first electrical line further includes a second resistor between the input connector and the first resistor.

34. The circuit block as recited in claim 33 wherein the first resistor has a resistance of 450 Ohms and the second resistor has a resistance of 5 Ohms.

35. The circuit block as recited in claim 31 wherein the first electrical line further includes a second resistor between the first resistor and the output connector.

36. The circuit block as recited in claim 35 wherein the first resistor has a resistance of 450 Ohms and the second resistor has a resistance of 5.56 Ohms.

37. The circuit block as recited in claim 21 wherein the electrical circuit further includes a ground line connected to the first electrical line via a first resistor and wherein the first electrical line further includes a capacitor and a second resistor in parallel between the input connector and the first resistor and a third resistor between the first resistor and the output connector.

38. The circuit block as recited in claim 21 wherein the electrical circuit further includes a second electrical line coupling the first and second output connectors to an input sampling port to an output sampling port.

39. The circuit block as recited in claim 38 wherein the electrical circuit is a single-ended pass-through circuit and the second electrical line coupling provides a percentage coupling between the first and second electrical lines.

40. The circuit block as recited in claim 39 wherein the percentage coupling is approximately 10 percent.
